(19) United States
(12) Patent Application Publication
(10) Pub. No.: US 2020/0124656 A1
(43) Pub. Date: Apr. 23, 2020

(54) METHOD AND SYSTEM FOR DETECTING AN INTERMITTENT DEFECT IN A TRANSMISSION LINE BY MEANS OF FILTERING

(71) Applicant: COMMISSARIAT A L'ENERGIE ATOMIQUE ET AUX ENERGIES ALTERNATIVES, PARIS (FR)

(72) Inventors: Christophe LAYER, PARIS (FR); Esteban CABANILLAS, ORSAY (FR)

(21) Appl. No.: 16/605,795

(22) PCT Filed: Apr. 18, 2018
(86) PCT No.: PCT/EP2018/059836

§ 371 Date: Oct. 16, 2019

(30) Foreign Application Priority Data
Apr. 19, 2017 (FR) 1753368

(51) Int. Cl. G01R 31/11; G01R 31/08

(52) U.S. Cl. CPC G01R 31/11; G01R 31/088

(57) ABSTRACT

A method for detecting an intermittent fault in a transmission line, includes the following steps: acquiring, at a point of the line, using a measurement device, a temporal measurement of a reference signal previously injected into the line using an injection device, reflected off a singularity of the line and propagated back to the point, filtering the temporal measurement of the signal using at least one filter that is predetermined depending on the spectral signature of a given type of fault, calculating the intercorrelation between at least one filtered signal and the reference signal so as to produce at least one time reflectogram, analyzing the at least one time reflectogram so as to characterize the possible presence of at least one intermittent fault on the transmission line.

The invention relates to the field of wire diagnostic systems based on the principle of reflectometry. One subject of the invention is a method for detecting intermittent faults in a transmission line, such as a cable, by applying a filter matched to the spectral signature of the fault.

Cables are omnipresent in all electrical systems in order to supply power or to transmit information. These cables are subjected to the same constraints as the systems that they link, and may be subject to failures. It is therefore necessary to be able to analyze their state and to provide information about the detection of faults, but also their location and their type, so as to assist with maintenance. Conventional reflectometry methods enable this type of test.

Reflectometry methods use a principle close to that of radar: an electrical signal, the probe signal or reference signal, which is more often than not high-frequency or wideband, is injected at one or more locations of the cable to be tested. The signal propagates in the cable or the network and returns a portion of its power when it encounters an electrical discontinuity. An electrical discontinuity may be caused for example by a connection, by the end of the cable or by a fault or more generally by an interruption of the propagation conditions for the signal in the cable. It is caused by a fault that locally modifies the characteristic impedance of the cable by bringing about a discontinuity in its linear parameters.

Analyzing the signals returned to the injection point makes it possible to deduce therefrom information about the presence and the location of these discontinuities, and therefore possible faults. An analysis in the time or frequency domain is usually performed. These methods are denoted using the acronyms TDR, stemming from the expression “time domain reflectometry”, and FDR, stemming from the expression “frequency domain reflectometry”.

The invention falls under the field of application of wire diagnostic methods, and is applicable to any type of electric cable, in particular power transmission cables or communication cables, in fixed or mobile installations, The cables in question may be coaxial, bifilar, in parallel rows, in twisted pairs or in another arrangement, provided that it is possible to inject a reflectometry signal into them at a point of the cable and to measure its reflection at the same point or at another point.

Reflectometry-based wire diagnostic systems are based on analyzing back-propagated signals in a cable under test. In order for the analysis to be relevant, it is necessary to acquire the signal several times and to average the acquisitions so as to reduce the level of measured noise caused in particular by imperfect components of the system, in particular analog-to-digital and digital-to-analog converters.

One drawback of using an average of several signal acquisitions is that this processing operation is expensive in terms of computational resources and especially in terms of time. Specifically, the duration required to calculate an average over several tens of acquisitions of signal portions comprising several hundred samples is all the greater the more the processing rate is imposed by the nature of the components that are used, which have to have little bulk in order to be embedded in a portable and inexpensive device.

One major drawback to this lengthy processing duration is that it is incompatible with detecting intermittent faults, that is to say faults that occur at a given instant and that are present for a short duration. This is the case for example for a short circuit having a limited duration in time.

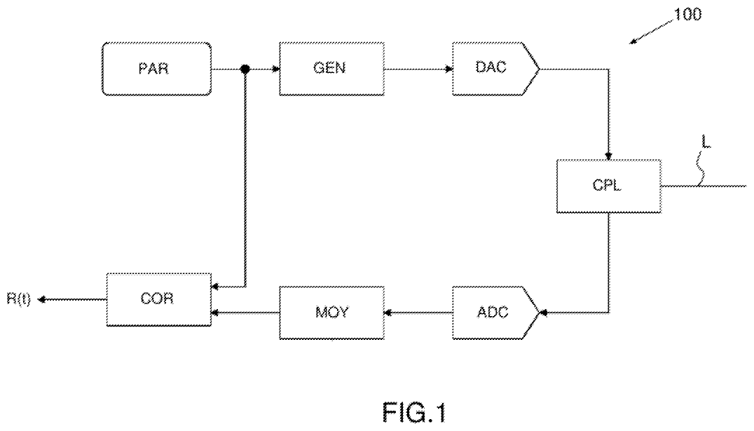

FIG. 1 shows a diagram of a system 100 for locating a fault in a transmission line L, such as a cable, using a conventional time reflectometry method from the prior art. Such a system primarily comprises a generator GEN for generating a reference signal based on parameters PAR defining the waveform of the signal. The generated digital reference signal is converted in an analog manner via a digital-to-analog converter DAC and is then injected at a point of the transmission line L by way of a directional coupler CPL. The signal propagates along the line and reflects off the singularities that it comprises. In the absence of a fault on the line, the signal reflects off the end of the line if the termination of the line is not matched. In the presence of a fault on the line, the signal reflects off the impedance discontinuity caused by the fault. The reflected signal is propagated back to a measurement point, which may be the same as the injection point or different. The back-propagated signal is measured via the directional coupler CPL and then converted digitally by an analog-to-digital converter ADC. A correlation COR is then made between the measured digital signal and a copy of the digital signal generated prior to injection in order to produce a time reflectogram R(t) corresponding to the intercorrelation between the two signals.

As is known in the field of time reflectometry-based diagnostic methods, the position dDF of a fault on the cable L, in other words its distance to the injection point of the signal, is able to be obtained directly based on the measurement, on the calculated time reflectogram R(t), of the duration tDF between the first amplitude peak shown on the reflectogram and the amplitude peak corresponding to the signature of the soft fault.

Various known methods may be contemplated to determine the position d_{DF}. A first method consists in applying the relationship linking distance and time: d_{DF}=V_{g}.t_{DF}, where V_{g} is the propagation speed of the signal in the cable. Another possible method consists in applying a proportionality relationship of the type d_{DF}/t_{DF}=L_{c}/t₀, where L_{c} is the length of the cable and t₀ is the duration, measured on the reflectogram, between the amplitude peak corresponding to the impedance discontinuity at the injection point and the amplitude peak corresponding to the reflection of the signal off the end of the cable. To reduce the level of measured noise, an average calculation MOY is performed before the correlation COR.

When it is desired specifically to detect the occurrence of intermittent faults, that is to say faults having a limited existence in time, generally of short duration, a stationary signal injected continuously into the cable L is used as reference signal. The stationary signal is formed for example of a sequence of samples having a predetermined duration, this sequence being reinjected successively and periodically. At the same time as the injection, the signal propagated back in the cable L is measured continuously.

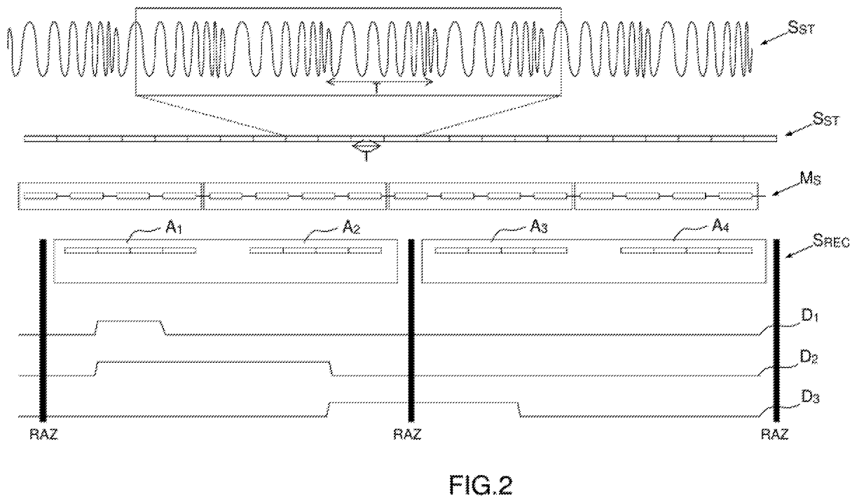

FIG. 2 shows one example of a stationary reference signal SST having a predetermined period T. This signal is injected continuously into the cable L. At the same time, the back-propagated signal Ms is measured or acquired continuously. To improve the accuracy of the analysis, the signal is oversampled by shifting the sampling clock of the analog-to-digital converter ADC every period T or multiples of this period T. The oversampled stationary signal SREC is then reconstructed. The average calculation MOY is applied to several periods of the oversampled stationary signal SREC. In the example of FIG. 2, consideration is given to four acquisition periods A₁,A₂,A₃,A₄ and an average over two acquisitions A₁ and A₂ or A₃ and A₄. Also shown are three examples of intermittent faults D1,D2,D3 having three different instants of occurrence and three different durations. The instants of occurrence of the faults correspond in fact to the instants of occurrence of their signature in the back-propagated and then processed signal. The first fault D1 occurs on the signal S_{REC} during the acquisition A₁ and has a very short duration which is shorter than the duration necessary to average two successive acquisitions A₁ and A₂. This fault D1 cannot be identified correctly by analyzing the signal S_{REC}, since the average has an attenuating effect on the signature of this fault in the signal. Specifically, for this scenario, a signal acquisition A₁ containing the signature of the fault is averaged with a signal acquisition A₂ not containing this signature.

The second fault D2 occurs at the same instant as D1 but has a longer duration, which means that the signature of the fault extends over the two acquisitions A₁ and A₂. This second fault D2 is able to be detected with a higher probability than the first fault D1.

Lastly, the third fault D3 has the same duration as the second fault D2, but straddles two successive acquisitions A₂ and A₃ corresponding to two different averages. This third fault D3 will not be identified correctly, just like the first fault D1, as the average calculation attenuates the signature of the fault.

More generally, it is observed that the longer the duration of the average calculation MOY, the greater the risk of not identifying faults of short duration or that occur between two acquisitions corresponding to two successive averages.

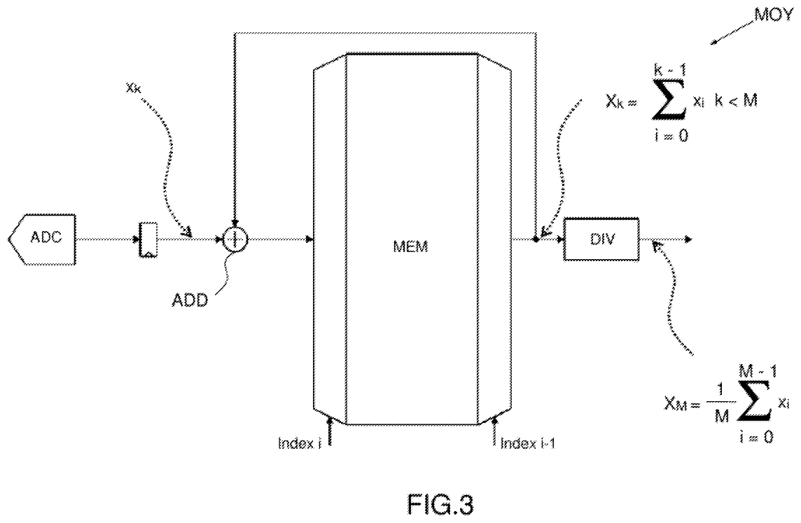

FIG. 3 outlines one exemplary implementation of the average calculation MOY using a memory MEM, an adder ADD and a divider DIV. The signal samples obtained at the output of the analog-to-digital converter ADC are stored in a memory MEM by periods. The memory MEM initially contains a period of the signal comprising N×P samples, where N is the number of points per period and P is the oversampling factor. The sum of k successive samples is taken by reading each sample from the memory MEM, by adding it to a new sample of the following period and then by storing the result in the memory MEM as a replacement for the previous sample. A divider DIV, for example a shift register, makes it possible to divide by M once the sum of M samples has been taken.

This implementation requires a memory able to contain N*P*W bits, where N is the number of points of a period of the stationary signal, P is the number of oversampling phases and W is the number of bits on which a sample is quantified, for example equal to 16 bits.

This solution not only does not make it possible to detect faults of short duration but also requires significant memory space to perform the average calculation.

To improve the detection of intermittent faults, in particular faults of the type of fault D3 in FIG. 2, one known solution consists in taking a sliding average rather than a fixed average. This solution makes it possible to detect faults of the type D3 that occur between two acquisitions corresponding to two different averages. However, it still does not make it possible to detect very short faults of the type D1 whose duration is less than the duration of an average.

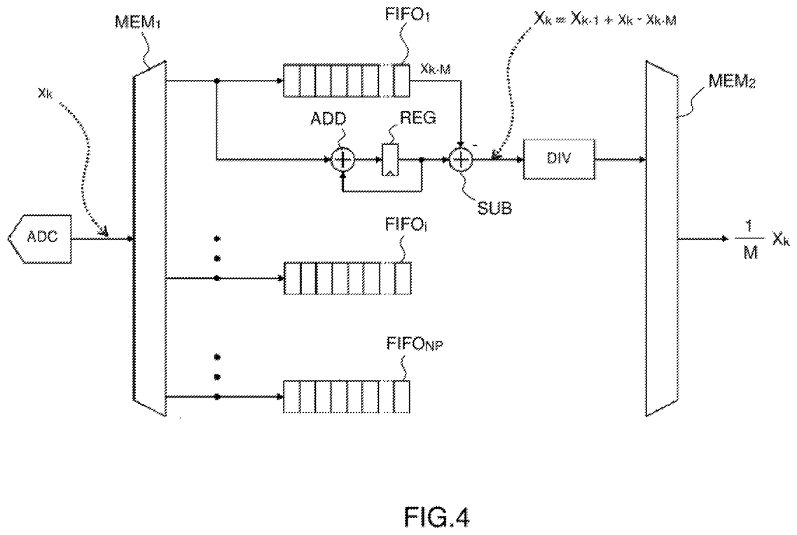

Furthermore, implementing a sliding average requires even more memory space than a conventional average, as is illustrated in FIG. 4.

A first memory MEM, makes it possible to store N.P samples of the reconstructed signal, corresponding to a period of the stationary signal. Next, for each sample of the period, an FIFO memory of size M is used with an adder ADD, a register REG and a subtractor SUB to calculate the sliding average over a horizon of M samples: Xₖ=Xₖ₋₁+Xₖ−X_{k-M}. A divider DIV makes it possible to divide the result by a factor M.

It is observed that this implementation requires the use of N.P separate FIFO memories, each of size M, thereby requiring memory space necessary for N.P.M samples each quantified on W bits. Using a sliding average thus does not make it possible to detect intermittent faults of short duration, and is furthermore expensive in terms of required memory space.

The invention proposes to mitigate the drawbacks of the abovementioned methods by replacing the average calculation MOY with one or more filter(s) matched depending on the characteristics of the faults to be detected, in particular their duration.

Moreover, the invention also aims to detect faults linked to anomalies that are harmful to the system under test. A reflectometry-based test system used to establish a diagnosis regarding a conductor associated with a complex system may produce alarms relating to intermittent faults that are caused, for example, by vibrations.

In the case of a conductor installed in an aircraft, a reflectometry system detects faults that are linked for example to certain vibrations inherent to the normal operation of an aircraft, such as engine vibrations. Other faults may by contrast highlight an anomaly that is potentially harmful to the integrity of the aircraft. For example, a vibratory phenomenon on the wings of the aircraft at a frequency close to the resonant frequency of the materials forming these wings corresponds to an anomaly that it is beneficial to detect.

The solutions from the prior art are not sufficient, since the usual systems do not have a functionality for targeting a fault, for example existing at a target frequency, depending on its specific characteristics.

The invention aims to solve this limitation by implementing one or more filter(s) matched to the faults that it is desired to precisely detect, for example faults whose origin is a phenomenon that is harmful at a given frequency. At the same time, the invention also makes it possible to ignore or to discriminate other frequencies that correspond to vibratory phenomena deemed to be not harmful or normal.

One subject of the invention is a method for detecting an intermittent fault in a transmission line, comprising the following steps:
Acquiring, at a point of the line, using a measurement device, a temporal measurement of a reference signal previously injected into the line using an injection device, reflected off a singularity of the line and propagated back to said point,
Filtering the temporal measurement of the signal using at least one filter that is predetermined depending on the spectral signature of a given type of fault,
Calculating the intercorrelation between at least one filtered signal and the reference signal so as to produce at least one time reflectogram,
Analyzing said at least one time reflectogram so as to characterize the possible presence of at least one intermittent fault on the transmission line.

According to one particular aspect of the invention, said at least one filter is determined at least based on the following steps:
Estimating the spectral signature of said given fault,
Determining said at least one filter as being the filter matched to the spectral signature.

According to one particular aspect of the invention, said at least one filter is determined at least based on the following steps:
Estimating the temporal response h(t) of said given fault,
Calculating the impulse response of said at least one filter as being the complex conjugate h*(−t) of the temporal response h(t),
Determining the coefficients of said at least one filter based on the impulse response of said at least one filter.

According to one particular aspect of the invention, the step of analyzing said at least one time reflectogram comprises:
searching for at least one amplitude peak characteristic of the signature of an intermittent fault,
measuring the temporal abscissa of the amplitude peak,
determining the position of the intermittent fault based on the measured temporal abscissa.

According to one particular aspect of the invention, said at least one filter is an infinite impulse response filter.

According to one variant implementation, the method according to the invention comprises the steps of:
Filtering the temporal measurement of the signal using a plurality of filters each predetermined depending on the spectral signature of a given type of fault that is different for each filter,
Calculating the intercorrelation between each filtered signal and the reference signal so as to produce a plurality of time reflectograms,
Analyzing the time reflectograms so as to characterize the possible presence of at least one intermittent fault on the transmission line.

According to one variant implementation, the method according to the invention comprises a step of generating and of injecting the reference signal into the transmission line.

Another subject of the invention is a system for detecting an intermittent fault in a transmission line comprising a measurement device able to acquire, at a point of the line, a temporal measurement of a reference signal previously injected into the line, reflected off a singularity of the line and propagated back to said point and:
at least one device for filtering the temporal measurement of the signal using at least one filter that is predetermined depending on the spectral signature of a given type of fault,
at least one device for calculating the intercorrelation between at least one filtered signal and the reference signal so as to produce at least one time reflectogram,
a device for analyzing said at least one time reflectogram so as to characterize the possible presence of at least one intermittent fault on the transmission line.

According to one particular variant, the system according to the invention comprises a display interface for displaying information characteristic of the presence of at least one fault on the transmission line and/or of the location of said at least one fault.

According to one particular variant, the system according to the invention comprises:
a plurality of devices for filtering the temporal measurement of the signal using a plurality of filters each predetermined depending on the spectral signature of a different given type of fault,
a plurality of devices for calculating the intercorrelation between each filtered signal and the reference signal so as to produce a plurality of time reflectograms,
a device for analyzing the time reflectograms so as to characterize the possible presence of at least one intermittent fault on the transmission line.

According to one particular variant, the system according to the invention comprises an injection device able to inject the reference signal into the transmission line.

Another subject of the invention is a computer program comprising instructions for executing the method for detecting an intermittent fault in a transmission line according to the invention when the program is executed by a processor,

Another subject of the invention is a recording medium able to be read by a processor and on which there is recorded a program comprising instructions for executing the method for detecting an intermittent fault in a transmission line according to the invention when the program is executed by a processor.

Other features and advantages of the present invention will become more clearly apparent upon reading the following description with reference to the appended drawings, in which:

FIG. 1 shows a diagram of a reflectometry-based wire diagnostic system according to the prior art,

FIG. 2 shows a plurality of charts illustrating the difficulties of detecting an intermittent fault using a conventional system,

FIG. 3 shows a diagram of one possible implementation of an average calculation as contemplated in a system from the prior art,

FIG. 4 shows a diagram of one possible implementation of a sliding average calculation as contemplated in a system from the prior art,

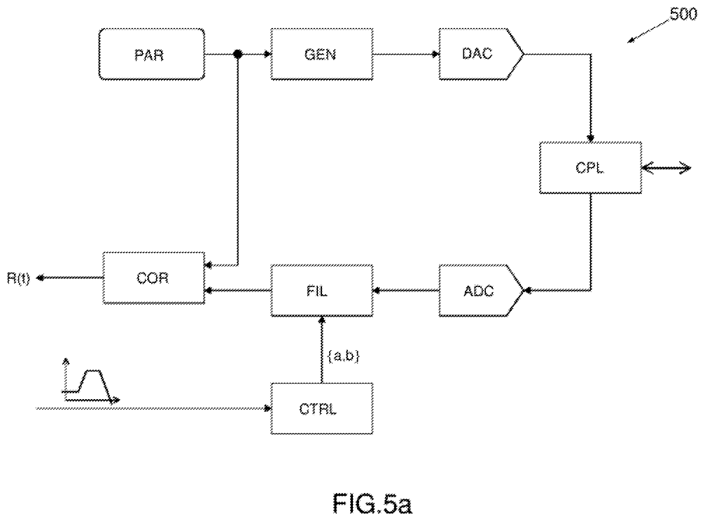

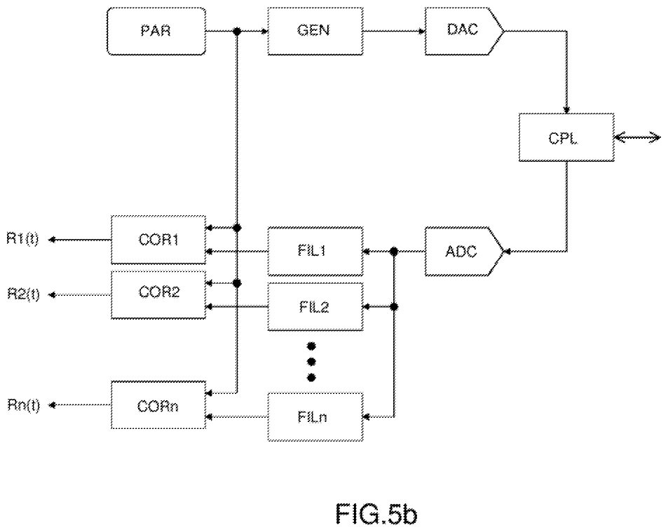

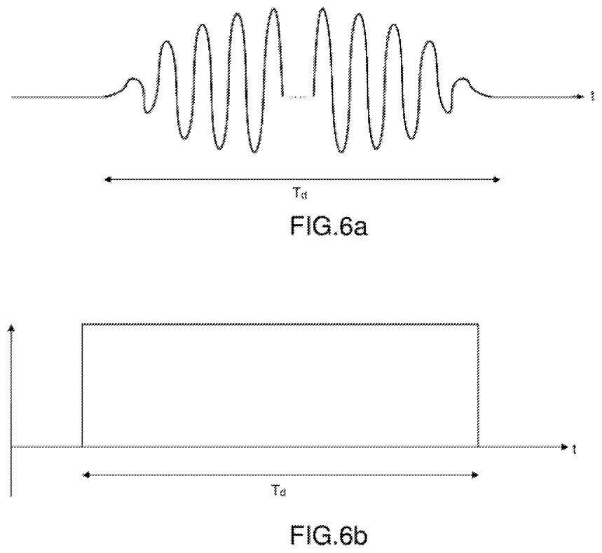

FIG. 5a shows a diagram of a system for detecting intermittent faults according to the invention,

FIG. 5b shows a diagram of a variant implementation of the system of FIG. 5a,

FIG. 6a shows one example of a temporal signal reflected off a vibratory intermittent fault,

FIG. 6b shows one example of a temporal signal reflected off a hard intermittent fault,

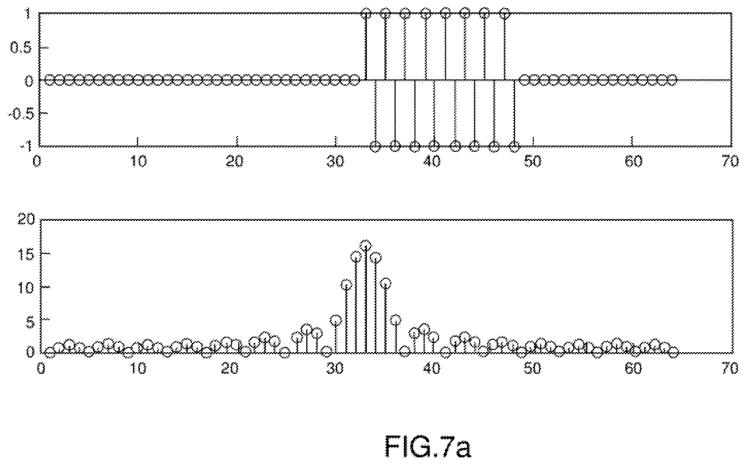

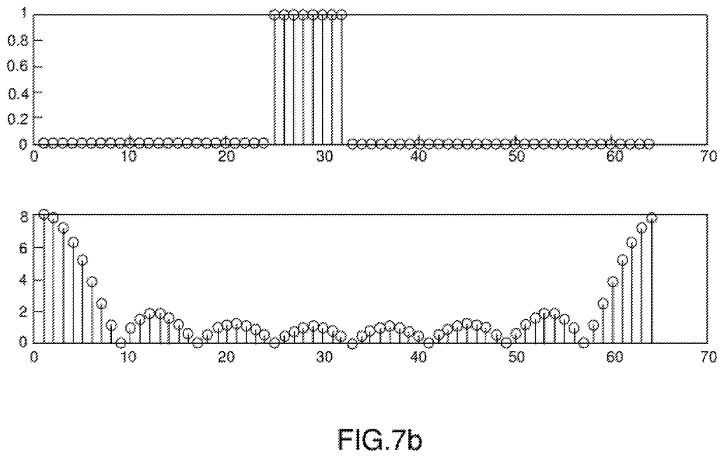

FIG. 7a shows a schematic depiction of the temporal response and of the frequency response of a vibratory intermittent fault,

FIG. 7b shows a schematic depiction of the temporal response and of the frequency response of a hard intermittent fault,

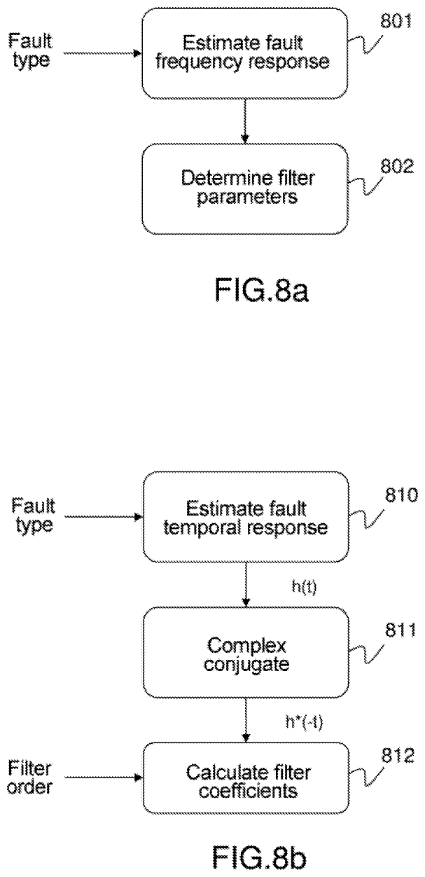

FIG. 8a shows a flowchart showing the various steps required to determine the parameters of the filter to be used in a system according to the invention,

FIG. 8b shows a flowchart showing one particular exemplary implementation of the method of FIG. 8a,

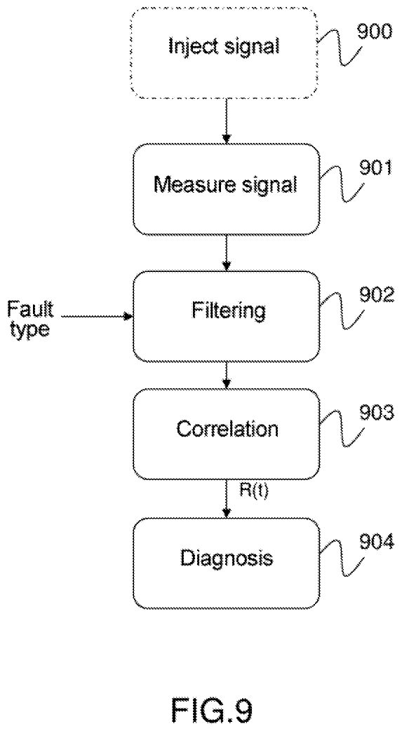

FIG. 9 shows a flowchart describing the steps for implementing the method for detecting intermittent faults according to the invention.

The invention proposes to replace the average calculation MOY with a filter matched to the characteristics of the intermittent fault that it is desired to detect.

FIG. 5a shows a wire diagnostic system 500 according to one embodiment of the invention. The system 500 comprises the same elements as the system 100 described in FIG. 1, except that the average calculation MOY is replaced by a filter FIL whose parameters are determined by a control unit CTRL depending on the characteristics of the spectral signature of an intermittent fault in the received signal.

Without departing from the scope of the invention, the portion of the system 500 that relates to the generation and the injection of the signal may be separate from the portion of the system 500 that relates to the acquisition of a measurement of the reflected signal and the processing operations relating to the filtering and to the intercorrelation calculation in order to produce a reflectogram R(t). In particular, two separate couplers CPL may be used, the first for injecting the reference signal at a first point of the line L and a second for measuring the back-propagated signal at a second point of the line L.

The parameters of the filter determined by the control unit CTRL comprise notably the bandwidth or the coefficients of the filter.

One advantage of using a filter instead of an average lies in the implementation complexity, which is reduced. Specifically, the filter FIL is able to be implemented with a lower number of coefficients, for example equal to two coefficients, thereby making its execution time and the memory space necessary to implement it more optimum than for an average calculation.

The filtering FIL may be implemented by way of an infinite impulse response filter, for example a linear recursive filter, notably a second-order filter. As an alternative, any other implementation of the filtering FIL may be employed, for example using a finite impulse response filter or an any-order filter.

The parameters of the filter are determined depending on the spectral or temporal signature of the intermittent fault that it is desired to detect.

The system according to the invention may comprise a plurality of filters FIL rather than just one, as shown in FIG. 5a, each filter being parameterized so as to be matched to the detection of one particular type of fault. If the system comprises a plurality of filters, each of the filters is controlled by the control unit CTRL, whose role is notably to select a filter, out of a plurality of available ones, depending on the type of fault to be detected.

FIG. 5b outlines one variant implementation of the system according to the invention in which a plurality of different filters FIL1, FIL2, . . . , FILn are used and are each connected to a different correlator COR1, COR2, . . . CORn.

In this variant implementation, the n filters associated with the n correlators operate in parallel. In other words, the digitized signal at the output of the ADC converter is processed in parallel by the n filters and n correlators. Each of the filters may be configured so as to detect a particular fault. In other words, each filter is different and has a response that is configured depending on the characteristics of a particular fault. One advantage of this variant is that it makes it possible to be able to detect several different types of fault at the same time. Of course, a control unit CTRL (not shown in FIG. 5b) may be used to configure the type of filter that is implemented in each filtering device.

Another advantage of this variant is that it makes it possible to track the evolution of a fault over time. For example, a progressive rupture in a conductor leads to a change in natural resonant frequency. By virtue of the system of FIG. 5b, it is possible to track the evolution of such a fault by configuring the bandwidths of the various filters such that each filter is able to discriminate the resonant frequency of the vibration induced by the fault at an instant of its evolution.

Another advantage of this variant is that it makes it possible to detect several different types of fault in parallel. This aspect of the invention makes it possible notably to discriminate the spectral signature of one fault that may be masked by that of another fault. This also makes it possible to track corrective measures taken to correct the fault.

The filters FIL, FIL2, . . . , FILn may be implemented in temporal or frequency form.

When an intermittent fault occurs on a transmission line under test into which a reference signal is injected, the signal reflects off the fault and is propagated back to the measurement point. The nature of the fault has an impact on the temporal form of the reflected signal.

FIG. 6a schematically shows the influence, on a temporal signal injected into a transmission line, of the reflection of this signal off a vibratory intermittent fault, for example caused by a short circuit, an open circuit or a fault generated by the vibrations of an apparatus. FIG. 6a shows only the influence of the fault on the reflected signal, the reflected signal itself being dependent on the type of signal injected into the line. The signal reflected off the singularity created by the fault is modulated by the estimated temporal response of the fault. The influence of a vibratory intermittent fault may be modeled by a sinusoidal signal of duration Td equal to the duration of the fault. The sinusoidal signal has a natural resonant frequency. Its envelope may be oval, as shown in FIG. 6a, or rectangular, or logarithmic or of another shape.

FIG. 6b shows the influence of another type of fault; this time it is a hard intermittent fault whose temporal response may be modeled by a time slot (or rectangle function) of duration T_{d} equal to the duration of the fault.

FIGS. 6a and 6b relate to two types of intermittent fault, but other intermittent faults may be contemplated insofar as it is possible to measure or to estimate their temporal response, in other words the influence of such a fault on a signal propagating in the transmission line and reflecting off the impedance discontinuity caused by the fault.

FIG. 7a shows two graphs respectively outlining the temporal response of a vibratory intermittent fault (upper figure) and its frequency response (lower figure).

The top of FIG. 7a shows a model of the temporal response of a vibratory intermittent fault of duration T_{d}. The bottom of FIG. 7a shows the frequency transform of the temporal response, obtained for example by way of a discrete Fourier transform.

In the same way, FIG. 7b shows the temporal response (top of FIG. 7b) and the frequency response (bottom of FIG. 7b) for a hard intermittent fault.

FIG. 8a shows, on a flowchart, the steps of a method for determining the parameters of the filter FIL used in a system according to the invention. The method receives, at input, the type of intermittent fault that it is desired to be able to detect, for example a hard fault or a vibratory fault.

In a first step 801, the frequency response of the fault, that is to say the spectrum of the signal generated by the occurrence of the fault, also called spectral signature of the fault, is estimated. The expression “spectral signature of a fault” signifies the influence, in the frequency response or the spectrum, of the signal reflected off a fault, of the fault itself, this influence varying depending on the nature of the fault, notably the type of fault (hard or vibratory) and its duration. In other words, when the signal injected into the cable is reflected off the impedance discontinuity created by the fault, it is propagated back while being modified by the influence of the fault. The spectrum of the signal propagated back off a fault may be considered to be the product of the spectrum of the signal injected into the line and the spectral signature of the fault.

In a second step 802, the filter FIL is determined as being the filter matched to the frequency response estimated in step 801. The filter is determined by its coefficients or its bandwidth or any other parameter making it possible to implement the filter.

FIG. 8b shows the steps of one particular implementation of the general method of FIG. 8a.

In a first step 810, the temporal response h(t) of the fault is estimated based on the type of fault that it is desired to detect. In a second step 811, the impulse response of the filter is determined as being the complex conjugate h*(−t) of the temporal response h(t) determined in step 810. In another step 812, the coefficients of the filter are then determined based on its impulse response and by choosing the order of the filter.

The coefficients of the filter are determined based on its impulse response using any digital resolution method or algorithm known to those skilled in the art, for example using the Steiglitz-McBride algorithm described in the document “A technique for the identification of linear systems, K. Steiglitz and L. E. McBride, IEEE trans. automat. con., vol. AC-10, pp. 461-464, October 1965”.

The filter that is used is preferably a low-pass or bandpass filter in order to filter high-frequency interference. It is more generally a matched filter.

In the case of a bandpass filter, the choice of the bandwidth of the filter results notably from a compromise between the detection accuracy for a particular fault and the filtered noise level. A narrow bandwidth leads to a lower detection gain but a noise level after filtering that is also lower. By contrast, a wider bandwidth leads to a higher noise level after filtering but a detection gain that is also higher, since the amplitude of the signature of the fault to be detected is amplified.

In the case of a vibratory fault, the bandwidth of the filter is preferably centered on the resonant frequency of the fault.

FIG. 9 summarizes the steps for implementing the method for detecting an intermittent fault according to the invention.

In a first step 900, a reference signal is injected at an injection point of a transmission line L. This step is not considered from the perspective of the method executed by a system 500 that does not comprise the portion relating to the generation and to the injection of the signal, which portion is implemented in a separate system.

In another step 901, the signal propagated back in the line L is measured at a measurement point. In a step 902, filtering parameterized depending on the type of fault to be detected is applied to the measured signal. The intercorrelation between the filtered signal and the signal generated prior to injection is then calculated 903.

In another step 904, a diagnosis is produced with regard to the presence of a fault and to its measured position on the reflectogram R(t) resulting from the intercorrelation calculation in step 903.

The result of the diagnosis may be provided to a user through a display interface. The displayed result may comprise an indication of the presence of a fault on the line and/or an indication relating to the position of the fault on the line.

The system according to any one of the variant implementations of the invention may be implemented by an electronic board on which the various components are arranged. The board may be connected to the cable to be analyzed by way of a coupling means CPL, which may be a capacitive-effect or inductive-effect directional coupler or else a resistive connection. The coupling device may be formed by physical connectors that link the signal generator to the cable or by contactless means, for example using a metal cylinder whose inner diameter is substantially equal to the outer diameter of the cable and that produces a capacitive coupling effect with the cable.

Furthermore, a processing unit, which is a computer, personal digital assistant or other equivalent electronic or computing device, may be used to drive the system according to the invention and display the results of the calculations that are performed on a human-machine interface, in particular the information about the detection and location of faults on the cable.

The method according to the invention, in particular the correlator COR and the filter or filters FIL may be implemented in an embedded or non-embedded processor or in a specific device. The processor may be a generic processor, a specific processor, an application-specific integrated circuit (ASIC) or a field-programmable gate array (FPGA). The device according to the invention may use one or more dedicated electronic circuits or a general-purpose circuit. The technique of the invention may be carried out on a reprogrammable calculation machine (a processor or a microcontroller for example) executing a program comprising a sequence of instructions, or on a dedicated calculation machine (for example a set of logic gates such as an FPGA or an ASIC, or any other hardware module).

The method according to the invention may also be implemented exclusively as a computer program, the method then being applied to a signal measurement previously acquired using a measurement device. In such a case, the invention may be implemented as a computer program comprising instructions for the execution thereof. The computer program may be recorded on a recording medium that is able to be read by a processor.

The reference to a computer program that, when it is executed, performs any one of the previously described functions is not limited to an application program running on a single host computer. On the contrary, the terms computer program and software are used here in a general sense to refer to any type of computer code (for example, application software, firmware, microcode, or any other form of computer instruction) that may be used to program one or more processors so as to implement aspects of the techniques described here. The computing means or resources may notably be distributed (“cloud completing”), possibly using peer-to-peer technologies. The software code may be executed on any suitable processor (for example a microprocessor) or processor core or a set of processors, whether they are provided in a single computing device or distributed between several computing devices (for example such as possibly accessible in the environment of the device). The executable code of each program allowing the programmable device to implement the processes according to the invention may be stored for example in the hard disk or in read-only memory. Generally speaking, the program or programs may be loaded into one of the storage means of the device before being executed. The central unit is able to command and direct the execution of the instructions or software code portions of the program or programs according to the invention, which instructions are stored in the hard disk or in the read-only memory or else in the other abovementioned storage elements.

1. A method for detecting an intermittent fault in a transmission line, comprising the steps of:
acquiring, at a point of the line, using a measurement device, a temporal measurement of a reference signal previously injected into the line using an injection device, reflected off a singularity of the line and propagated back to said point,
filtering the temporal measurement of the signal using at least one filter that is predetermined depending on the spectral signature of a given type of fault,
calculating the intercorrelation between at least one filtered signal and the reference signal so as to produce at least one time reflectogram,
analyzing said at least one time reflectogram so as to characterize the possible presence of at least one intermittent fault on the transmission line.

2. The method for detecting an intermittent fault of claim 1, wherein said at least one filter is determined at least based on the following steps:
estimating the spectral signature of said given fault,
determining said at least one filter as being the filter matched to the spectral signature.

3. The method for detecting an intermittent fault of claim 1, wherein said at least one filter is determined at least based on the following steps:
estimating the temporal response h(t) of said given fault,
calculating the impulse response of said at least one filter as being the complex conjugate h*(−t) of the temporal response h(t),
determining the coefficients of said at least one filter based on the impulse response of said at least one filter.

4. The method for detecting an intermittent fault of claim 1, wherein the step of analyzing said at least one time reflectogram comprises:
searching for at least one amplitude peak characteristic of the signature of an intermittent fault,
measuring the temporal abscissa of the amplitude peak,
determining the position of the intermittent fault based on the measured temporal abscissa.

5. The method for detecting an intermittent fault of claim 1, wherein said at least one filter is an infinite impulse response filter.

6. The method for detecting an intermittent fault of claim 1, comprising the steps of:
filtering the temporal measurement of the signal using a plurality of filters each predetermined depending on the spectral signature of a given type of fault that is different for each filter,
calculating the intercorrelation between each filtered signal and the reference signal so as to produce a plurality of time reflectograms,
analyzing the time reflectograms so as to characterize the possible presence of at least one intermittent fault on the transmission line.

7. The method for detecting an intermittent fault of claim 1, comprising a step of generating and of injecting the reference signal into the transmission line.

8. A system for detecting an intermittent fault in a transmission line comprising a measurement device able to acquire, at a point of the line, a temporal measurement of a reference signal previously injected into the line, reflected off a singularity of the line and propagated back to said point and:
at least one device for filtering the temporal measurement of the signal using at least one filter that is predetermined depending on the spectral signature of a given type of fault,
at least one device for calculating the intercorrelation between at least one filtered signal and the reference signal so as to produce at least one time reflectogram,
a device for analyzing said at least one time reflectogram so as to characterize the possible presence of at least one intermittent fault on the transmission line.

9. The system for detecting an intermittent fault of claim 8, comprising a display interface for displaying information characteristic of the presence of at least one fault on the transmission line and/or of the location of said at least one fault.

10. The system for detecting an intermittent fault of claim 8, comprising:
a plurality of devices for filtering the temporal measurement of the signal using a plurality of filters each predetermined depending on the spectral signature of a different given type of fault,
a plurality of devices for calculating the intercorrelation between each filtered signal and the reference signal so as to produce a plurality of time reflectograms,
a device for analyzing the time reflectograms so as to characterize the possible presence of at least one intermittent fault on the transmission line.

11. The system for detecting an intermittent fault of claim 8, comprising an injection device able to inject the reference signal into the transmission line.

12. A computer program comprising instructions stored on a tangible non-transitory storage medium for executing on a processor a method for detecting an intermittent fault in a transmission line, comprising the steps of:
acquiring, at a point of the line, using a measurement device, a temporal measurement of a reference signal previously injected into the line using an injection device, reflected off a singularity of the line and propagated back to said point,
filtering the temporal measurement of the signal using at least one filter that is predetermined depending on the spectral signature of a given type of fault,
calculating the intercorrelation between at least one filtered signal and the reference signal so as to produce at least one time reflectogram,
analyzing said at least one time reflectogram so as to characterize the possible presence of at least one intermittent fault on the transmission line.

13. A tangible non-transitory processor-readable recording medium on which is recorded a program comprising instructions for executing a method for detecting an intermittent fault in a transmission line, comprising the steps of:
acquiring, at a point of the line, using a measurement device, a temporal measurement of a reference signal previously injected into the line using an injection device, reflected off a singularity of the line and propagated back to said point,
filtering the temporal measurement of the signal using at least one filter that is predetermined depending on the spectral signature of a given type of fault,
calculating the intercorrelation between at least one filtered signal and the reference signal so as to produce at least one time reflectogram,
analyzing said at least one time reflectogram so as to characterize the possible presence of at least one intermittent fault on the transmission line.
